(19) United States
(12) Patent Application Publication
(10) Pub. No.: US 2026/0054427 A1
(43) Pub. Date: Feb. 26, 2026

(54) RELEASE FILM, METHOD FOR PRODUCING THE SAME, AND PACKAGING APPARATUS

(71) Applicant: NAN YA PLASTICS CORPORATION, TAIPEI (TW)

(72) Inventors: CHING-YAO YUAN, TAIPEI (TW); CHUN-CHE TSAO, TAIPEI (TW); Li-Yu Kao, TAIPEI (TW)

(21) Appl. No.: 18/930,996

(22) Filed: Oct. 29, 2024

(30) Foreign Application Priority Data
Aug. 20, 2024 (TW) 113131178

(51) Int. Cl. B29C 37/00; B29K 63/00; B29L 31/34; C09J 7/25; C09J 7/30; C09J 7/40; H01L 21/56

(52) U.S. Cl. CPC B29C 37/0075; C09J 7/255; C09J 7/30; C09J 7/401; H01L 21/566; B29K 2063/00; B29K 2867/003; B29L 2031/3406; C09J 2203/326

(57) ABSTRACT

A release film, method for producing the same, and packaging apparatus are provided. The release film includes a PET base layer and a release layer. The release layer is formed by coating a coating liquid onto the PET base layer. The coating liquid includes a base material having a glass transition temperature (Tg) of between −60° C. and −30° C. and a plurality of inorganic particles dispersed in the base material. An average particle size of the inorganic particles is between 8 μm and 12 μm. A thickness of the release layer is between 5 μm and 20 μm, and a surface roughness (Ra) of the release layer is between 0.4 μm and 0.8 μm. The release layer is configured to be in contact with an epoxy resin, and a release force between the release layer and the epoxy resin is between 50 gf/inch and 400 gf/inch.

### CROSS-REFERENCE TO RELATED PATENT APPLICATION

This application claims the benefit of priority to Taiwan Patent Application No. 113131178, filed on Aug. 20, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a release film, a method for producing the same, and a packaging apparatus, and more particularly to a release film that has excellent release property with an epoxy resin, a method for producing the same, and a packaging apparatus.

### BACKGROUND OF THE DISCLOSURE

A conventional release film usually includes a base layer and a release layer formed on the base layer, and a surface of the release layer is usually too flat, such that residual gas cannot be easily expelled when a packaging resin (e.g., an epoxy resin) is disposed on the surface of the release layer. In addition, a tightness between the release film and a carrying board of a packaging member during packaging lamination is insufficient, such that the packaging resin can easily leak out from a groove of a mold and cause surface defects.

### SUMMARY OF THE DISCLOSURE

In response to the above-referenced technical inadequacies, the present disclosure provides a release film, method for producing the same, and packaging apparatus, so as to effectively improve on the issues of a conventional release film (e.g., a fluidity of a packaging resin on a surface of a release film is too high and a packaging resin easily leaks out from a groove of a mold).

In order to solve the above-mentioned problems, one of the technical aspects adopted by the present disclosure is to provide a release film. The release includes a PET base layer and a release layer. The release layer is formed by coating a coating liquid onto the PET base layer. The coating liquid includes a base material and inorganic particles. The base material has a glass transition temperature (Tg) of between −60° C. and −30° C. The inorganic particles are dispersed in the base material. An average particle size of the inorganic particles is between 8 μm and 12 μm. A thickness of the release layer is between 5 μm and 20 μm, and a surface roughness (Ra) of the release layer is between 0.4 μm and 0.8 μm. The release layer of the release film is configured to be in contact with an epoxy resin, and a release force between the release layer and the epoxy resin is between 50 gf/inch and 400 gf/inch.

In one of the possible or preferred embodiments, a number average molecular weight of the base material is between 900 and 1,100, and a weight average molecular weight of the base material is between 90,000 and 110,000.

In one of the possible or preferred embodiments, the base material is selected from the group consisting of butyl acrylate (BA), butyl methacrylate (BMA), and 2-hydroxyethyl acrylate (2HEA). The inorganic particles are silicon dioxide particles.

In one of the possible or preferred embodiments, based on a content of the coating liquid being 100 wt %, a content of the base material is between 70 wt % and 95 wt %, and a content of the inorganic particles is between 1 wt % and 12 wt %.

In one of the possible or preferred embodiments, the coating liquid further includes a bridging agent and a lubricant. Based on a content of the coating liquid being 100 wt %, a content of the bridging agent is between 8 wt % and 15 wt %, and a content of the lubricant is between 0.1 wt % and 5 wt %.

In one of the possible or preferred embodiments, a material of the base material is a PET resin with a model number LL216 made by Nan Ya Plastics Corporation. According to the ASTM D1204 test standard, a longitudinal thermal deformation rate of the release film is between 0.4% and 0.6%, and a transverse thermal deformation rate of the release film is between 0.15% and 0.25%.

In order to solve the above-mentioned problems, another one of the technical aspects adopted by the present disclosure is to provide a packaging apparatus. The packaging apparatus includes a packaging mold and a release film. The packaging mold is recessed to form an accommodating groove. The release film is disposed in the accommodating groove. The release film includes a PET base layer and a release layer. The PET base layer is disposed at a bottom surface of the accommodating groove of the packaging mold. The release layer is formed by coating a coating liquid onto the PET base layer. The coating liquid includes a base material and a plurality of inorganic particles dispersed in the base material. A glass transition temperature (Tg) of the base material is between −60° C. and −30° C., an average particle size of the inorganic particles is between 8 μm and 12 μm, a thickness of the release layer is between 5 μm and 20 μm, and a surface roughness (Ra) of the release layer is between 0.4 μm and 0.8 μm. The release layer of the release film is configured to be in contact with an epoxy resin, and a release force between the release layer and the epoxy resin is between 50 gf/inch and 400 gf/inch.

In order to solve the above-mentioned problems, yet another one of the technical aspects adopted by the present disclosure is to provide a method for producing a release film. The method includes a coating liquid preparing process and a coating process. The coating liquid preparing process is implemented by adding a plurality of inorganic particles into a solvent and stirring at a stirring speed of between 1,000 rpm and 2,000 rpm for 2 minutes to 8 minutes, and then adding a base material and stirring at a stirring speed of between 1,000 rpm and 2,000 rpm for 12 minutes to 18 minutes to form a coating liquid. A glass transition temperature (Tg) of the base material is between −60° C. and −30° C., and an average particle size of the inorganic particles is between 8 μm and 12 μm. The coating process is implemented by coating the coating liquid onto a PET base layer to form a release layer thereon, so as to form a release film. A thickness of the release layer is between 5 μm and 20 μm, and a surface roughness (Ra) of the release layer is between 0.4 μm and 0.8 μm. The release layer of the release film is configured to be in contact with an epoxy resin, and a release force between the release layer and the epoxy resin is between 50 gf/inch and 400 gf/inch.

In one of the possible or preferred embodiments, a number average molecular weight of the base material is between 900 and 1,100, and a weight average molecular weight of the base material is between 90,000 and 110,000.

In one of the possible or preferred embodiments, the base material is selected from the group consisting of butyl acrylate (BA), butyl methacrylate (BMA), and 2-hydroxyethyl acrylate (2HEA). The inorganic particles are silicon dioxide particles.

In one of the possible or preferred embodiments, based on a content of the coating liquid being 100 wt %, a content of the base material is between 70 wt % and 95 wt %, and a content of the inorganic particles is between 1 wt % and 12 wt %.

In one of the possible or preferred embodiments, in the coating liquid preparing process, after the base material is added, a bridging agent and a lubricant are further added and stirred at a stirring speed of 1,000 rpm and 2,000 rpm for 8 minutes to 12 minutes to form the coating liquid. Based on a content of the coating liquid being 100 wt %, a content of the bridging agent is between 8 wt % and 15 wt %, and a content of the lubricant is between 0.1 wt % and 5 wt %.

In one of the possible or preferred embodiments, a material of the base material is a PET resin with a model number LL216 made by Nan Ya Plastics Corporation. According to the ASTM D1204 test standard, a longitudinal thermal deformation rate of the release film is between 0.4% and 0.6%, and a transverse thermal deformation rate of the release film is between 0.15% and 0.25%.

Therefore, in the release film, method for producing the same, and packaging apparatus provided by the present disclosure, by virtue of “the glass transition temperature (Tg) of the base material being between −60° C. and −30° C.” and “the average particle size of the inorganic particles being between 8 μm and 12 μm,” the issues of a conventional release film (e.g., a fluidity of a packaging resin on a surface of a release film being too high and a packaging resin easily leaking out from a groove of a mold) can be effectively improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a release film according to an embodiment of the present disclosure;

FIG. 2A is a schematic view of a packaging apparatus according to the embodiment of the present disclosure;

FIG. 2B is a schematic view showing the packaging apparatus packaging a chip according to the embodiment of the present disclosure; and

FIG. 3 is a flowchart of a method for producing a release film according to the embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### [Release Film]

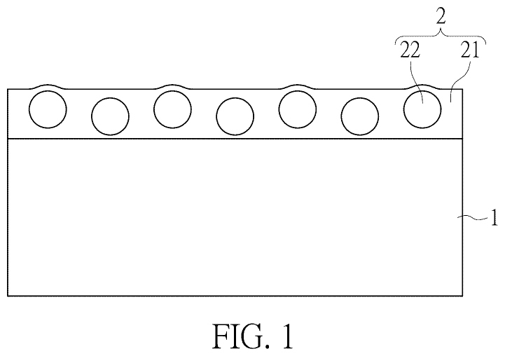

Referring to FIG. 1, the present disclosure provides a release film 100. The release film 100 includes a PET base layer 1 and a release layer 2. The release film 100 can be applied to a packaging procedure, but the present disclosure is not limited thereto.

A thickness of the PET base layer 1 can be between 25 μm and 250 μm. Preferably, the thickness of the PET base layer 1 is between 30 μm and 100 μm. More preferably, the thickness of the PET base layer 1 is about 38 μm. A material of the base material is a PET resin with a model number LL216 made by Nan Ya Plastics Corporation, but the present disclosure is not limited thereto.

The release layer 2 is formed by coating a coating liquid onto the PET base layer 1. The coating liquid includes a base material 21 and a plurality of inorganic particles 22 dispersed in the base material 21. Since the base material 21 has the inorganic particles 22 dispersed therein, a surface roughness at a surface of the release layer 2 away from the PET base layer 1 can be increased, thereby adjusting a liquidity of a packaging resin (e.g., an epoxy resin) on the release layer 2. In other words, if the base material 21 does not have the inorganic particles 22 dispersed therein, the surface of the release layer 2 away from the PET base layer 1 is too flat, and accordingly, residual gas at the surface cannot be easily expelled when the packaging resin flows and fills into gaps. In addition, the surface of the release layer 2 has slight undulations because of the inorganic particles 22, a surface of the packaging resin correspondingly has slight undulations after being in contact with the surface of the release film 100, and accordingly, a font contrast during laser engraving can be improved.

A glass transition temperature (Tg) of the base material 21 is between-60° C. and −30° C. It is worth mentioning that, since the base material 21 has a relatively low glass transition temperature (e.g., between −60° C. and −30° C.), the release layer 2 is relatively soft and can tightly fit to a packaging board, such that the packaging resin does not easily leak out from an accommodating groove of a mold.

In the present embodiment, a number average molecular weight of the base material 21 can be between 900 and 1,100, and a weight average molecular weight of the base material 21 can be between 90,000 and 110,000, but the present disclosure is not limited thereto.

In addition, in the present embodiment, the base material 21 is selected from the group consisting of butyl acrylate (BA), butyl methacrylate (BMA), and 2-hydroxyethyl acrylate (2HEA), but the present disclosure is not limited thereto.

An average particle size of the inorganic particles 22 is between 8 μm and 12 μm. Preferably, the average particle size of the inorganic particles 22 can be about 9 μm, but the present disclosure is not limited thereto. If the average particle size of the inorganic particles 22 is too high or too low, the surface roughness of the release layer 2 would be too high or too low. The inorganic particles 22 can be silicon dioxide particle.

A thickness of the release layer 2 is between 5 μm and 20 μm, and a surface roughness (Ra) of the release layer is between 0.4 μm and 0.8 μm. Preferably, the thickness of the release layer 2 is between 8 μm and 15 μm, and a surface roughness (Ra) of the release layer is between 0.5 μm and 0.7 μm. More preferably, the thickness of the release layer 2 is about 12 μm.

Based on a content of the coating liquid being 100 wt %, a content of the base material 21 can be between 70 wt % and 95 wt %, and a content of the inorganic particles 22 can be between 1 wt % and 12 wt %. Preferably, based on the content of the coating liquid being 100 wt %, the content of the base material 21 is between 70 wt % and 85 wt %, and the content of the inorganic particles 22 is between 5 wt % and 11.11 wt %. More preferably, based on the content of the coating liquid being 100 wt %, the content of the base material 2 is between 75 wt % and 80 wt %, and the content of the inorganic particles 22 is between 5.88 wt % and 11.11 wt %.

In one embodiment, the coating liquid can further include a bridging agent and a lubricant. Based on the content of the coating liquid being 100 wt %, a content of the bridging agent is between 8 wt % and 15 wt %, and a content of the lubricant is between 0.1 wt % and 5 wt %. Preferably, based on the content of the coating liquid being 100 wt %, the content of the bridging agent is between 9.2 wt % and 10.96 wt %, and the content of the lubricant is between 0.1 wt % and 0.35 wt %.

It is worth mentioning that, through the materials and the content ranges of the PET base layer 1 and the release layer 2, the release film 100 has relative low thermal deformation rates along a longitudinal direction and a transverse direction. In the release film 100 has excessive longitudinal thermal deformation rate or excessive transverse thermal deformation rate, the release film 100 easily detaches from a packaging mold 200 during packaging. Specifically, according to the ASTM D1204 test standard, a longitudinal thermal deformation rate of the release film is between 0.4% and 0.6%, and a transverse thermal deformation rate of the release film is between 0.15% and 0.25%.

The release layer 2 of the release film 100 is configured to be in contact with an epoxy resin E, and a release force between the release layer 2 and the epoxy resin E is between 50 gf/inch and 400 gf/inch.

### [Packaging Apparatus]

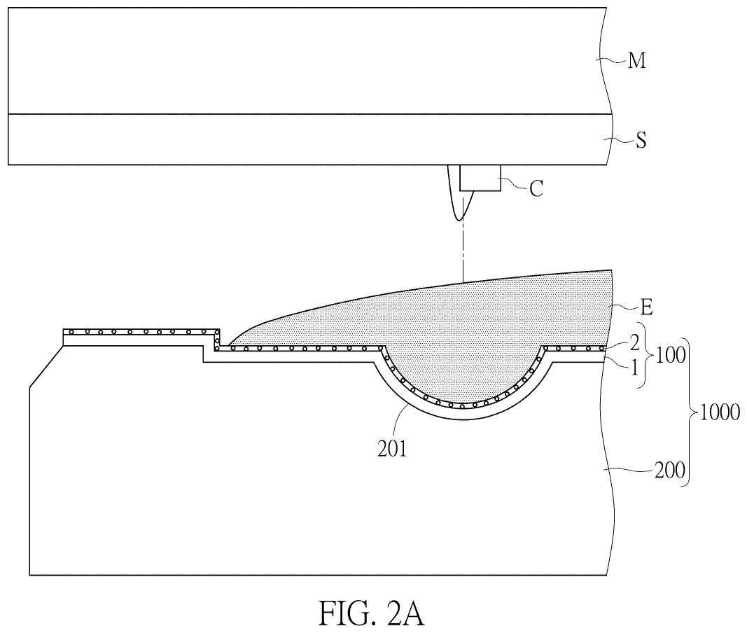

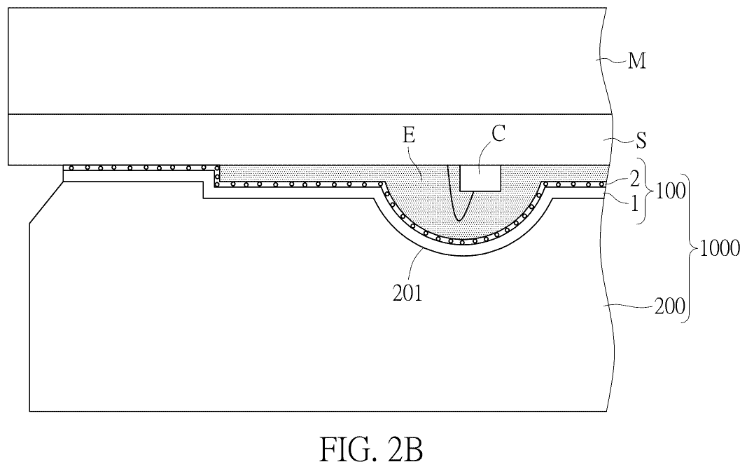

Referring to FIG. 2A and FIG. 2B, FIG. 2A is a schematic view of a packaging apparatus according to the embodiment of the present disclosure, and FIG. 2B is a schematic view showing the packaging apparatus packaging a chip according to the embodiment of the present disclosure. The embodiment of the present disclosure further provides a packaging apparatus 1000. The packaging apparatus 1000 includes a release film 100 and a packaging mold 200. The packaging mold 200 is recessed to form an accommodating groove 201, and the release film 100 is disposed in the accommodating groove 201.

The release film 100 includes a PET base layer 1 and a release film 2. The PET base layer 1 is disposed at a bottom surface of the accommodating groove 201 of the packaging mold 200. The release film 2 is formed by coating a coating liquid onto the PET base layer 1. The coating liquid includes a base material 21 and inorganic particles 22 dispersed in the base material 21. A glass transition temperature (Tg) of the base material 21 is between −60° C. and −30° C., an average particle size of the inorganic particles 22 is between 8 μm and 12 μm, a thickness of the release layer 2 is between 5 μm and 20 μm, and a surface roughness (Ra) of the release layer 2 is between 0.4 μm and 0.8 μm. The release layer 2 of the release film 100 is configured to be in contact with an epoxy resin E, and a release force between the release layer 2 and the epoxy resin E is between 50 gf/inch and 400 gf/inch.

The packaging apparatus 1000 is configured to package at least one chip C. Naturally, the packaging apparatus 1000 can be used to package a plurality of chips C at the same time, and the packaged chips C can be cut and separated in a subsequent procedure. The chip C can be disposed at one side of a packaging board S, and the packaging board S can be disposed on a carrying mold M. When the packaging apparatus 1000 and the carrying mold M jointly package the chip C, the release film 100 tightly fit to the packaging mold 200 and the packaging board S, and the epoxy resin E does not leak between the packaging mold 200 and the packaging board S.

### [Method for Producing a Release Film]

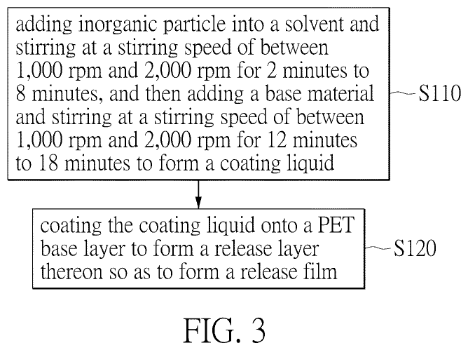

Referring to FIG. 3, FIG. 3 is a flowchart of a method for producing a release film according to the embodiment of the present disclosure. The embodiment of the present disclosure further provides a method for producing a release film. The above-mentioned release film 100 can be obtained by implementing the method for producing the release film, but the present disclosure is not limited thereto. The method for producing the release film includes a coating liquid preparing process S110 and a coating process S120.

The coating liquid preparing process S10 is implemented by adding inorganic particles 22 into a solvent and stirring at a stirring speed of between 1,000 rpm and 2,000 rpm for 2 minutes to 8 minutes, and then adding a base material 21 and stirring at a stirring speed of between 1,000 rpm and 2,000 rpm for 12 minutes to 18 minutes to form a coating liquid. The solvent can be, for example, ethyl acetate, but the present disclosure is not limited thereto.

Preferably, in the coating liquid preparing process S110, the inorganic particles 22 is added into the solvent and stirred at a stirring speed of about 1,500 rpm for about 5 minutes, and then the base material 21 is added and stirred at a stirring speed of about 1,500 rpm for 15 minutes to form the coating liquid.

In the coating liquid preparing process S110 of one embodiment, after the base material 21 is added, a bridging agent and a lubricant are further added and stirred at a stirring speed of 1,000 rpm and 2,000 rpm for 8 minutes to 12 minutes to form the coating liquid. Preferably, the lubricant and the bridging agent are added and then stirred at a stirring speed of 1,500 rpm for about 10 minutes to form the coating liquid.

Based on a content of the coating liquid being 100 wt %, a content of the base material is between 70 wt % and 95 wt %, a content of the inorganic particles is between 1 wt % and 12 wt %, a content of the bridging agent is between 8 wt % and 15 wt %, and a content of the lubricant is between 0.1 wt % and 5 wt %.

The coating process S120 is implemented by coating the coating liquid onto a PET base layer 1 to form a release layer 2 thereon, so as to form a release film 100.

### [Experimental Results]

Hereinafter, a more detailed description will be provided with reference to Exemplary Examples 1 to 5 and Comparative Examples 1 to 3. However, the following Exemplary Examples are only used to aid in understanding of the present disclosure, and are not to be construed as limiting the scope of the present disclosure.

Exemplary Example 1: in the release film, the thickness of the release layer is 12 μm, the thickness of the PET base layer is 38 μm, based on the content of the release layer being 100 wt %, the content of the base material is 84.28 wt %, the content of the inorganic particles is 5.88 wt %, the content of the lubricant is 0.1 wt %, the content of the bridging agent is 9.74 wt %, and the average particle size of the inorganic particles is 9.56 μm.

Exemplary Example 2: in the release film, the thickness of the release layer is 12 μm, the thickness of the PET base layer is 38 μm, based on the content of the release layer being 100 wt %, the content of the base material is 83.06 wt %, the content of the inorganic particles is 7.24 wt %, the content of the lubricant is 0.1 wt %, the content of the bridging agent is 9.6 wt %, and the average particle size of the inorganic particles is 9.56 μm.

Exemplary Example 3: in the release film, the thickness of the release layer is 12 μm, the thickness of the PET base layer is 38 μm, based on the content of the release layer being 100 wt %, the content of the base material is 81.87 wt %, the content of the inorganic particles is 8.57 wt %, the content of the lubricant is 0.1 wt %, the content of the bridging agent is 9.46 wt %, and the average particle size of the inorganic particles is 9.56 μm.

Exemplary Example 4: in the release film, the thickness of the release layer is 12 μm, the thickness of the PET base layer is 38 μm, based on the content of the release layer being 100 wt %, the content of the base material is 80.72 wt %, the content of the inorganic particles is 9.86 wt %, the content of the lubricant is 0.1 wt %, the content of the bridging agent is 9.32 wt %, and the average particle size of the inorganic particles is 9.56 μm.

Exemplary Example 5: in the release film, the thickness of the release layer is 12 μm, the thickness of the PET base layer is 38 μm, based on the content of the release layer being 100 wt %, the content of the base material is 79.59 wt %, the content of the inorganic particles is 11.11 wt %, the content of the lubricant is 0.1 wt %, the content of the bridging agent is 9.2 wt %, and the average particle size of the inorganic particles is 9.56 μm.

Comparative Example 1: in the release film, the thickness of the release layer is 12 μm, the thickness of the PET base layer is 38 μm, the release layer does not include inorganic particles, based on the content of the release layer being 100 wt %, the content of the base material is 84.8 wt %, and the content of the bridging agent is 15.2 wt %.

Comparative Example 2: in the release film, the thickness of the release layer is 12 μm, the thickness of the PET base layer is 38 μm, the release layer does not include inorganic particles, based on the content of the release layer being 100 wt %, the content of the base material is 84.1 wt %, the content of the lubricant is 0.9 wt %, and the content of the bridging agent is 15 wt %.

Comparative Example 3: in the release film, the thickness of the release layer is 12 μm, the thickness of the PET base layer is 38 μm, based on the content of the release layer being 100 wt %, the content of the base material is 83.18 wt %, the content of the inorganic particles is 4.83 wt %, and the content of the bridging agent is 11.99 wt %, and the average particle size of the inorganic particles is 9.56 μm.

For the release film of each of Exemplary Examples 1 to 5 and Comparative Examples 1 to 3, components of the release film, thickness of the release layer, thickness of the PET base material, particle size of the inorganic particles, release force between the release layer and the epoxy resin, surface roughness (Ra) of the release layer, longitudinal thermal deformation and transverse thermal deformation of the release film, and hundred grid test and hardness test results are listed in Table 1 below. The relevant test methods are also described as follows.

Release force test is carried out according to ASTM D3330 at an angle of 90 degrees.

Thermal deformation test is carried out according to ASTM D1204 at a temperature of 150° C. for 10 minutes.

Hundred grid test is carried out according to ASTM D3359.

Hardness test is carried out according to ASTM D3363.

TABLE 1
[Components of Exemplary Examples and Comparative Examples
and Test Results of Their Physical and Chemical Properties]

| | Exemplary | Exemplary | Exemplary | Exemplary | Exemplary | Comparative | Comparative | Comparative |
|---|---|---|---|---|---|---|---|---|
| Item | Example 1 | Example 2 | Example 3 | Example 4 | Example 5 | Example 1 | Example 2 | Example 3 |
| Thickness | 12 | 12 | 12 | 12 | 12 | 12 | 8 | 20 |
| of release | | | | | | | | |
| layer | | | | | | | | |
| (μm) | | | | | | | | |
| Thickness | 38 | 38 | 38 | 38 | 38 | 38 | 38 | 38 |
| of PET | | | | | | | | |
| base layer | | | | | | | | |
| (μm) | | | | | | | | |
| Content of | 84.28 | 83.06 | 81.87 | 80.72 | 79.59 | 84.8 | 84.1 | 83.18 |
| base | | | | | | | | |
| material | | | | | | | | |
| in release | | | | | | | | |
| layer | | | | | | | | |
| (wt %) | | | | | | | | |
| Material | BA, | BA, | BA, | BA, | BA, | BzMA, | BzMA, | BA, |
| of base | BMA, | BMA, | BMA, | BMA, | BMA, | 2HEMA | 2HEMA | BMA, |
| material | 2HEA | 2HEA | 2HEA | 2HEA | 2HEA | | | 2HEA |
| Content of | 5.88 | 7.24 | 8.57 | 9.86 | 11.11 | 0.00 | 0.00 | 4.83 |
| inorganic | | | | | | | | |
| particles | | | | | | | | |
| in release | | | | | | | | |
| layer | | | | | | | | |
| (wt %) | | | | | | | | |
| Average | 9.56 | 9.56 | 9.56 | 9.56 | 9.56 | — | — | 9.56 |
| particle | | | | | | | | |
| size of | | | | | | | | |
| inorganic | | | | | | | | |
| particles | | | | | | | | |
| (μm) | | | | | | | | |
| Content of | 0.10% | 0.10% | 0.10% | 0.10% | 0.10% | 0.00% | 0.90% | 0.00% |
| lubricant | | | | | | | | |
| in release | | | | | | | | |
| layer | | | | | | | | |
| (wt %) | | | | | | | | |
| Content of | 9.74 | 9.60 | 9.46 | 9.32 | 9.20 | 15.20 | 15.00 | 11.99 |
| bridging | | | | | | | | |
| agent in | | | | | | | | |
| release | | | | | | | | |
| layer | | | | | | | | |
| (wt %) | | | | | | | | |
| Release | 373 | 329 | 328 | 297 | 252 | 724 | 41 | 414 |
| force | | | | | | | | |
| between | | | | | | | | |
| release | | | | | | | | |
| layer and | | | | | | | | |
| epoxy | | | | | | | | |
| resin | | | | | | | | |
| (gf/inch) | | | | | | | | |
| Surface | 0.403 | 0.533 | 0.663 | 1.146 | 1.628 | 0.010 | 0.011 | 0.085 |
| roughness | | | | | | | | |
| (Ra) of | | | | | | | | |
| release | | | | | | | | |
| layer | | | | | | | | |
| (μm) | | | | | | | | |
| Longitudinal | 0.52 | 0.48 | 0.52 | 0.48 | 0.51 | 0.52 | 0.51 | 0.51 |
| thermal | | | | | | | | |
| deformation | | | | | | | | |
| rate of | | | | | | | | |
| release | | | | | | | | |
| film (%) | | | | | | | | |
| Transverse | 0.20 | 0.20 | 0.20 | 0.19 | 0.19 | 0.20 | 0.21 | 0.21 |
| thermal | | | | | | | | |
| deformation | | | | | | | | |
| rate of | | | | | | | | |
| release | | | | | | | | |
| film (%) | | | | | | | | |
| Hundred | 5B | 5B | 5B | 5B | 5B | 5B | 5B | 5B |
| grid test | | | | | | | | |
| Hardness | 6B | 6B | 6B | 6B | 6B | 1H | 1H | 6B |
| test | | | | | | | | |
| Packaging | PASS | PASS | PASS | PASS | PASS | NG | NG | PASS |
| test (glue | | | | | | | | |
| leakage) | | | | | | | | |
| Packaging | PASS | PASS | PASS | PASS | PASS | NG | NG | NG |
| test | | | | | | | | |
| (residual | | | | | | | | |
| foam) | | | | | | | | |

### [Discussion of Test Results]

As shown in Comparative example 1, the film surface is not added with inorganic particles, the surface roughness of the release layer is 0.01 μm, which shows that the film surface without the inorganic particles is flat and does not have undulations, the hardness of the film surface is relatively high (i.e., 1H), and the release film has glue leakage and residual foam during packaging test.

As shown in Comparative Example 2, when 0.9 wt % of lubricant is added in the formula, the release force is obviously decreased, but the glue leakage at edge issue and residual foam issue still exist.

As shown in Comparative Example 3, when the thickness of the coating layer is greater than the particle size of the particle, the surface roughness of the film surface decreases to 0.085 μm, which shows when the thickness of the coating layer is excessive, the particle cannot emerge from the coating layer, thereby causing the surface roughness to decrease. However, when the material of the main resin is changed to the determined material, the hardness of the film surface is decreased, such that the film surface can preferably fit to the packaging board at laminating condition to improve on the glue leakage issue.

As shown in the Comparative Examples, when the content of the particle is adjusted, the surface roughness of the film surface increases with the increase of the content of the particle, which shows that the surface roughness increases with more particle emerge. When the surface roughness of the film surface is between 0.4 μm and 1.6 μm, the packaging appearance is intact, and no residual foam or glue leakage issue occurs.

### Beneficial Effects of the Embodiment

In conclusion, in the release film, method for producing the same, and packaging apparatus provided by the present disclosure, by virtue of “the glass transition temperature (Tg) of the base material being between −60° C. and −30° C.” and “the average particle size of the inorganic particles being between 8 μm and 12 μm,” the issues of a conventional release film (e.g., a fluidity of a packaging resin on a surface of a release film being too high and a packaging resin easily leaking out from a groove of a mold) can be effectively improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A release film, comprising:
a PET base layer; and
a release layer formed by coating a coating liquid onto the PET base layer, wherein the coating liquid includes:
a base material having a glass transition temperature (Tg) of between −60° C. and −30° C.; and
a plurality of inorganic particles dispersed in the base material, wherein an average particle size of the inorganic particles is between 8 μm and 12 μm;
wherein a thickness of the release layer is between 5 μm and 20 μm, and a surface roughness (Ra) of the release layer is between 0.4 μm and 0.8 μm;
wherein the release layer of the release film is configured to be in contact with an epoxy resin, and a release force between the release layer and the epoxy resin is between 50 gf/inch and 400 gf/inch.

2. The release film according to claim 1, wherein a number average molecular weight of the base material is between 900 and 1,100, and a weight average molecular weight of the base material is between 90,000 and 110,000.

3. The release film according to claim 1, wherein the base material is selected from the group consisting of butyl acrylate (BA), butyl methacrylate (BMA), and 2-hydroxyethyl acrylate (2HEA), and wherein the inorganic particles are silicon dioxide particles.

4. The release film according to claim 1, wherein, based on a content of the coating liquid being 100 wt %, a content of the base material is between 70 wt % and 95 wt %, and a content of the inorganic particle is between 1 wt % and 12 wt %.

5. The release film according to claim 1, wherein the coating liquid further includes a bridging agent and a lubricant, and wherein, based on a content of the coating liquid being 100 wt %, a content of the bridging agent is between 8 wt % and 15 wt %, and a content of the lubricant is between 0.1 wt % and 5 wt %.

6. The release film according to claim 1, wherein a material of the base material is a PET resin with a model number LL216 made by Nan Ya Plastics Corporation, wherein according to the ASTM D1204 test standard, a longitudinal thermal deformation rate of the release film is between 0.4% and 0.6%, and a transverse thermal deformation rate of the release film is between 0.15% and 0.25%.

7. A packaging apparatus, comprising:
a packaging mold recessed to form an accommodating groove; and
a release film disposed in the accommodating groove, wherein the release film includes:
a PET base layer disposed at a bottom surface of the accommodating groove of the packaging mold; and
a release layer formed by coating a coating liquid onto the PET base layer, wherein the coating liquid includes a base material and inorganic particle dispersed in the base material, and wherein a glass transition temperature (Tg) of the base material is between −60° C. and −30° C., an average particle size of the inorganic particle is between 8 μm and 12 μm, a thickness of the release layer is between 5 μm and 20 μm, and a surface roughness (Ra) of the release layer is between 0.4 μm and 0.8 μm;
wherein the release layer of the release film is configured to be in contact with an epoxy resin, and a release force between the release layer and the epoxy resin is between 50 gf/inch and 400 gf/inch.

8. A method for producing a release film, comprising:
a coating liquid preparing process implemented by adding inorganic particle into a solvent and stirring at a stirring speed of between 1,000 rpm and 2,000 rpm for 2 minutes to 8 minutes, and then adding a base material and stirring at a stirring speed of between 1,000 rpm and 2,000 rpm for 12 minutes to 18 minutes to form a coating liquid, wherein a glass transition temperature (Tg) of the base material is between −60° C. and −30° C., and an average particle size of the inorganic particle is between 8 μm and 12 μm; and
a coating process implemented by coating the coating liquid onto a PET base layer to form a release layer thereon so as to form a release film, wherein a thickness of the release layer is between 5 μm and 20 μm, and a surface roughness (Ra) of the release layer is between 0.4 μm and 0.8 μm;
wherein the release layer of the release film is configured to be in contact with an epoxy resin, and a release force between the release layer and the epoxy resin is between 50 gf/inch and 400 gf/inch.

9. The method according to claim 8, wherein a number average molecular weight of the base material is between 900 and 1,100, and a weight average molecular weight of the base material is between 90,000 and 110,000.

10. The method according to claim 8, wherein the base material is selected from the group consisting of butyl acrylate (BA), butyl methacrylate (BMA), and 2-hydroxyethyl acrylate (2HEA), and wherein the inorganic particle is silicon dioxide particle.

11. The method according to claim 8, wherein, based on a content of the coating liquid being 100 wt %, a content of the base material is between 70 wt % and 95 wt %, and a content of the inorganic particle is between 1 wt % and 12 wt %.

12. The method according to claim 8, wherein, in the coating liquid preparing process, after the base material is added, a bridging agent and a lubricant are further added and stirred at a stirring speed of 1,000 rpm and 2,000 rpm for 8 minutes to 12 minutes to form the coating liquid, and wherein, based on a content of the coating liquid being 100 wt %, a content of the bridging agent is between 8 wt % and 15 wt %, and a content of the lubricant is between 0.1 wt % and 5 wt %.

13. The method according to claim 8, wherein a material of the base material is a PET resin with a model number LL216 made by Nan Ya Plastics Corporation, and wherein according to the ASTM D1204 test standard, a longitudinal thermal deformation rate of the release film is between 0.4% and 0.6%, and a transverse thermal deformation rate of the release film is between 0.15% and 0.25%.
